(19) United States
(12) Patent Application Publication
(10) Pub. No.: US 2010/0073032 A1
(43) Pub. Date: Mar. 25, 2010

(54) VOLTAGE COMPARATOR AND ELECTRONIC DEVICE

(75) Inventors: Akira ABE, Sapporo-shi (JP); Yukinari SHIBATA, Sapporo-shi (JP)

Correspondence Address: OLIFF & BERRIDGE, PLC, P.O. BOX 320850, ALEXANDRIA, VA, 22320-4850, US

(73) Assignee: SEIKO EPSON CORPORATION, Tokyo (JP)

(21) Appl. No.: 12/558,916

(22) Filed: Sep. 14, 2009

(30) Foreign Application Priority Data
Sep. 19, 2008 (JP) 2008-240395

(51) Int. Cl. H03K 5/00; G05F 1/10

(52) U.S. Cl. 327/50; 327/538

(57) ABSTRACT

A differential amplifier circuit, a differentiation circuit and an output amplifier circuit are provided. The differential amplifier circuit differentially amplifies differentially inputted signals and provides an output. The differentiation circuit differentiates the output of the differential amplifier circuit, and adds the differentiated output to a bias voltage of a constant current transistor of the output amplifier circuit. A voltage comparator capable of higher speed operation without increasing its current consumption is provided.

This application claims priority to Japanese patent application No. 2008-240395 filed Sep. 19, 2008, and the said application is herein incorporated in the present specification.

### BACKGROUND OF THE INVENTION

1. Technical Field

The present invention relates to voltage comparators that compare an input voltage with a reference voltage and output an output voltage according to a comparison result.

2. Description of Related Technology

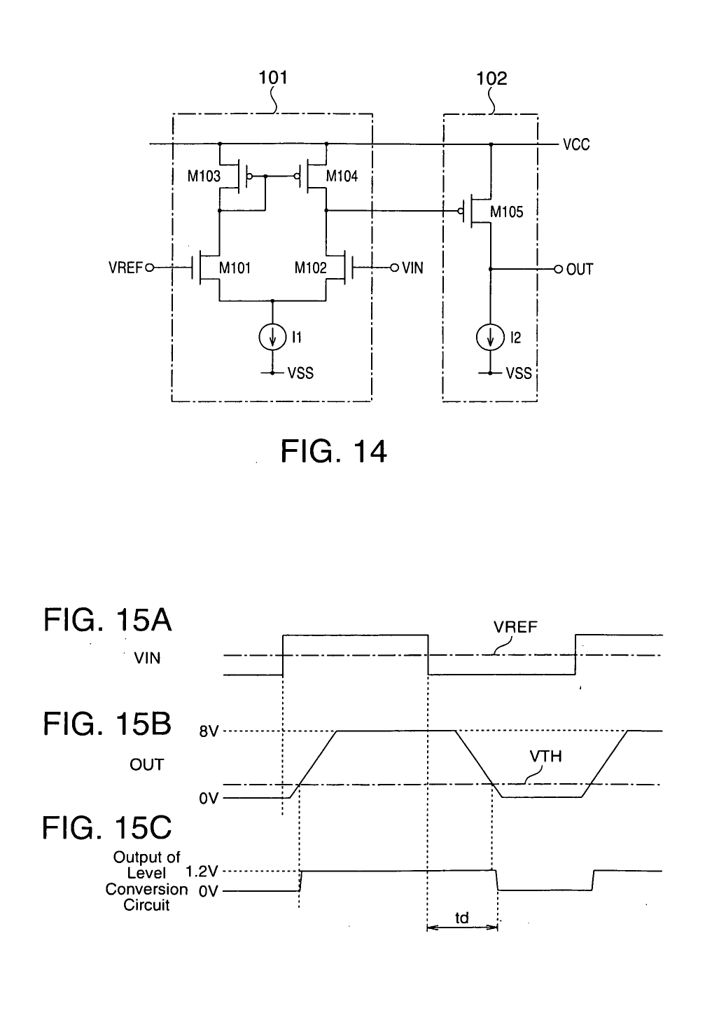

As a voltage comparator of this type, for example, one equipped with a differential amplifier 101 at an input stage and an output amplifier 102 at an output stage, as shown in FIG. 14, is known (see Japanese Laid-open Patent Application HEI6-109779 or the like).

The differential amplifier 101 is equipped with N type MOS transistors M101 and M101 that compose a differential pair, P type MOS transistors M103 and M104 that compose a load, and an electric current source I1. The output amplifier 102 is a drain grounded amplifier circuit that is formed from a P type MOS transistor M105 and an electric current source 12.

Next, an example of operations of the voltage comparator shown in FIG. 14 will be described with reference to FIG. 15. In this example, for example, 8 [V] is applied as a power supply voltage VCC of the voltage comparator of FIG. 14.

It is assumed that an input voltage VIN and a reference voltage VREF shown in FIG. 15(A) are differentially inputted to the differential amplifier 101. In this case, when the input voltage VIN becomes to be more than the reference voltage VREF, an output OUT of the output amplifier 102 changes from 0 [V] to 8 [V]. Thereafter, when the input voltage VIN becomes to be less than the reference voltage VREF, the output OUT of the output amplifier 102 changes from 8 [V] to 0 [V] (see FIG. 15(B)).

Let us consider a case where a level converter circuit (not shown) that converts the level of an output of the voltage comparator is connected to a rear stage (a succeeding stage) of the voltage comparator shown in FIG. 14. Here, let us assume that, as a power supply voltage of the level converter circuit, for example, 1.2 [V] is applied.

In this case, when the output OUT of the output amplifier 102 becomes to be greater than a threshold voltage VTH of an inverter circuit composing the level converter circuit, the output of the level converter circuit changes from 0 [V] to 1.2 [V], as shown in FIG. 15(C). Thereafter, when the output OUT of the output amplifier 102 becomes to be less than the threshold voltage VTH, the output of the level converter circuit changes from 1.2 [V] to 0 [V] as shown in FIG. 15(C).

In this manner, when the voltage comparator shown in FIG. 14 includes a level converter circuit, and when the level converter circuit level-converts the output OUT of the voltage comparator to a level lower than that of the output OUT, the following inconvenience occurs.

Namely, when the input voltage VIN of the voltage comparator rises, the output of the level converter circuit rises in a relatively short time. However, when the input voltage VIN of the voltage comparator falls, the output of the level converter circuit falls after a delay time td has elapsed from the fall of the input voltage VIN (see FIG. 15(C)). This causes an inconvenience in that the output response time is deteriorated such that a high-speed response cannot be achieved.

In order to solve such an inconvenience and achieve high-speed, for example, bias currents of the current sources I1 and I2 of the differential amplifier 101 and the output amplifier 102 may be increased. However, if they are increased, another inconvenience of an increased current consumption of the voltage comparator would occur.

If a CMOS inverter is used as the level converter circuit to be connected to the succeeding stage of the voltage comparator of FIG. 14, a flow-through current corresponding to the transition time of the output OUT of the voltage comparator flows through the CMOS inverter.

For this reason, it was difficult to accomplish high-speed response and low current consumption at once. In other words, the longer the response time of the voltage comparator, the longer the time in which the flow-through current flows through the CMOS inverter composing the level converter circuit, which is desired to be solved in the case of application thereof to a system that emphasizes low power consumption.

In particular, the aforementioned inconvenience would become more significant, when the power supply voltage of the voltage comparator is relatively higher than the power supply voltage of the level converter circuit (logic circuit) to be connected to the succeeding stage of the voltage comparator, and the difference between these power supply voltages becomes greater.

### SUMMARY OF THE INVENTION

In accordance with some embodiments of the present invention, it is possible to provide, for example, a voltage comparator or the like that is capable of achieving high-speed without increasing current consumption.

### MEANS TO SOLVE THE PROBLEMS

To solve the problems described above and achieve the object of the invention, the inventions are composed of the following structures, respectively.

A first invention includes a differential amplifier circuit that differentially amplifies differentially inputted signals and provides an output, an output amplifier circuit that amplifies the output of the differential amplifier circuit and provides an output, and a differentiation circuit that differentiates the output of the differential amplifier circuit, wherein a differentiation output of the differentiation circuit is added to a bias voltage of a constant current transistor of the output amplifier circuit.

In accordance with a second invention, in the first invention, the output amplifier circuit is equipped with an input transistor in which an output of the differential amplifier circuit is inputted, and a constant current transistor that supplies a constant current to the input transistor.

In accordance with a third invention, in the first or the second invention, the differentiation circuit is comprised of a capacitor and a resistance.

In accordance with a fourth invention, in the third invention, the resistance is formed from a resistance disposed above a semiconductor substrate and having a predetermined resistance value, wherein the resistance is divided into N pieces such that a parasitic capacitance between endmost terminals thereof formed as disposed on the semiconductor substrate is minimized, and each of the resistances divided in N pieces is arranged according to a predetermined rule on the semiconductor substrate.

In accordance with a fifth invention, in the fourth invention, each of the resistances divided in N pieces has a predetermined width and a predetermined length, and the resistances divided in N pieces are sequentially arranged on the semiconductor substrate at predetermined intervals and connected in series.

In accordance with a sixth invention, in the first˜fifth inventions, there is further provided a level converter circuit that converts the level of an output of the output amplifier circuit, and the level converter circuit operates with a relatively lower power supply voltage than a power supply voltage for the differential amplifier circuit and the output amplifier circuit.

In accordance with a seventh invention, in the first˜sixth invention, there is further provided a constant current circuit that generates a predetermined electric current, and a current mirror circuit that circulates a constant electric current through the constant current transistor based on the electric current generated by the constant current circuit.

In accordance with an eighth invention, in the seventh invention, the constant current circuit is equipped with a diode-connected first transistor, n pieces of freely selectable second transistors having gates to which a predetermined potential is applied and having different transistor sizes, and m pieces of freely selectable resistances having different resistance values.

In accordance with a ninth invention, in the eighth invention, the n pieces of second transistors are connected in parallel and the m pieces of resistances are connected in series, and there are provided a first selection device that selects at least one of the n pieces of transistors connected in parallel and a second selection device that selects at least one of the m pieces of resistances connected in series.

In accordance with a tenth invention, in the ninth invention, each of the n pieces of transistors is comprised of p pieces of transistors having the same size wherein the p pieces of transistors are connected in series and have gates that are commonly connected, and a predetermined potential is applied to the commonly connected portion, and has a switch for selecting the p pieces of serially connected transistors.

An eleventh invention includes a differential amplifier circuit that differentially amplifies differentially inputted signals and provides an output, a bias circuit that generates a bias voltage from a constant electric current, a differentiation circuit to which the output of the differential amplifier circuit and the bias voltage are applied, and an output amplifier circuit to which the output of the differential amplifier circuit and an output of the differentiation circuit are applied.

A twelfth invention pertains to an electronic device that includes any one of the first˜eleventh inventions.

In accordance with the present invention, the differentiation circuit is provided, such that it is possible to realize a voltage comparator that can achieve higher speed without increasing its current consumption.

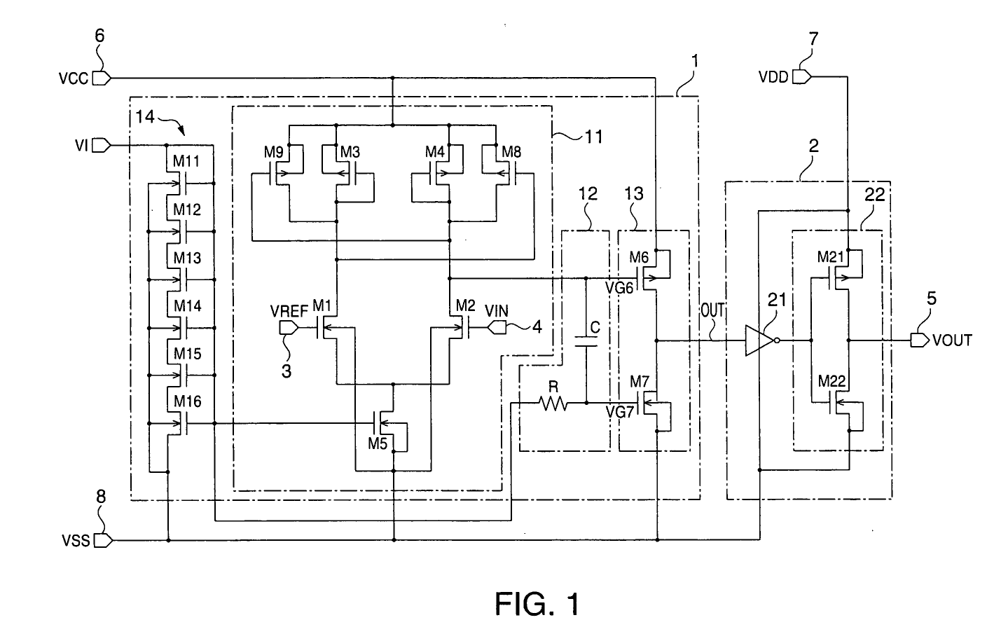

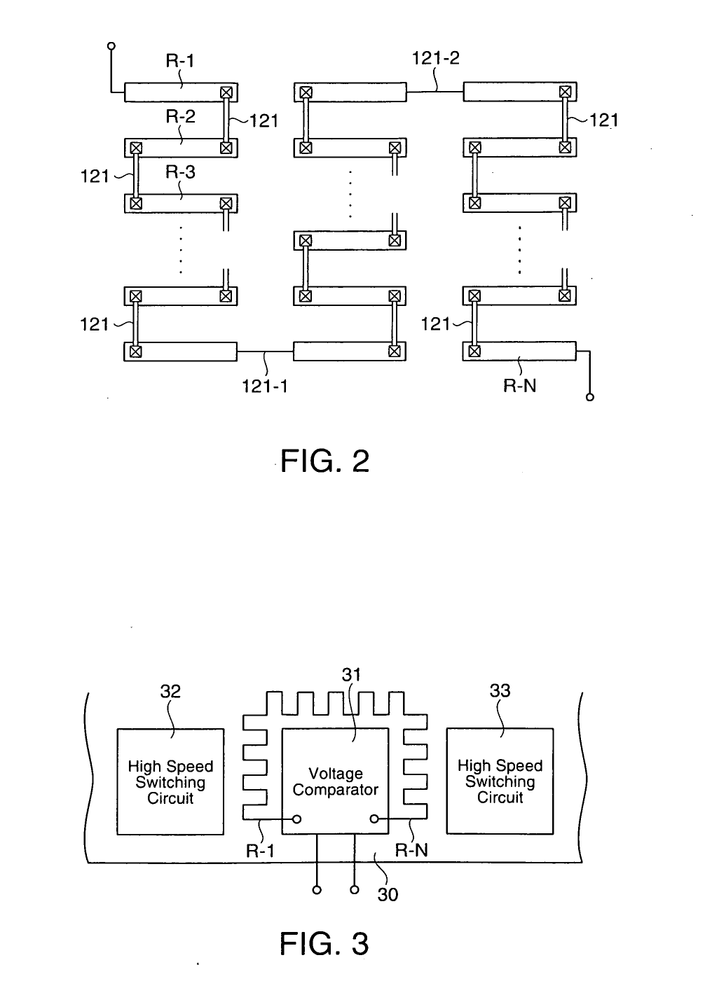

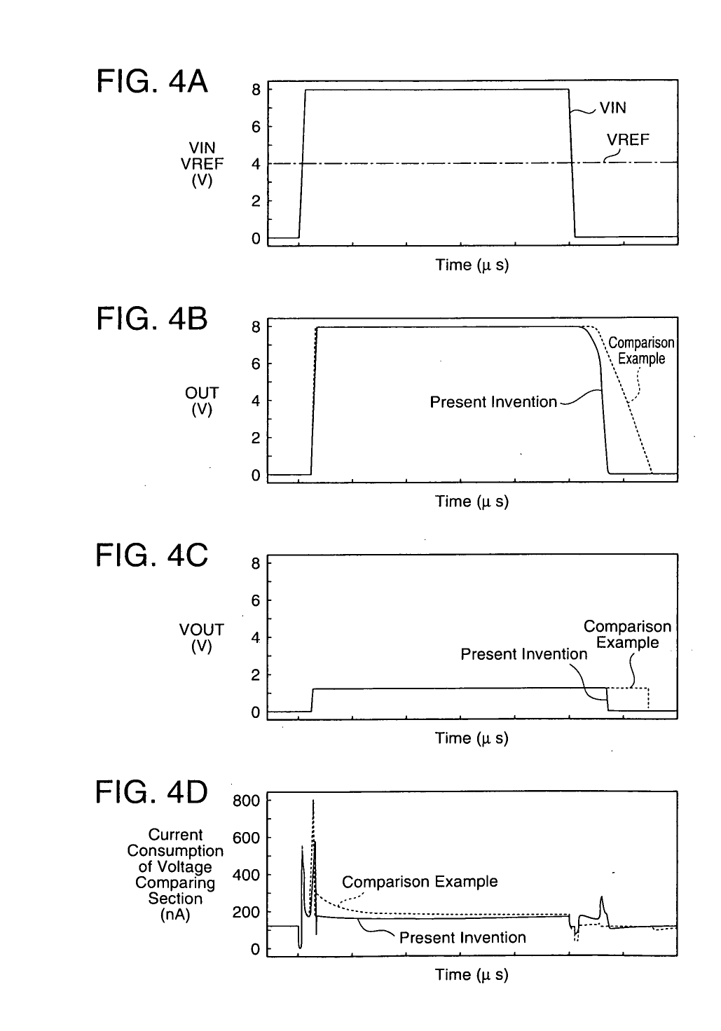

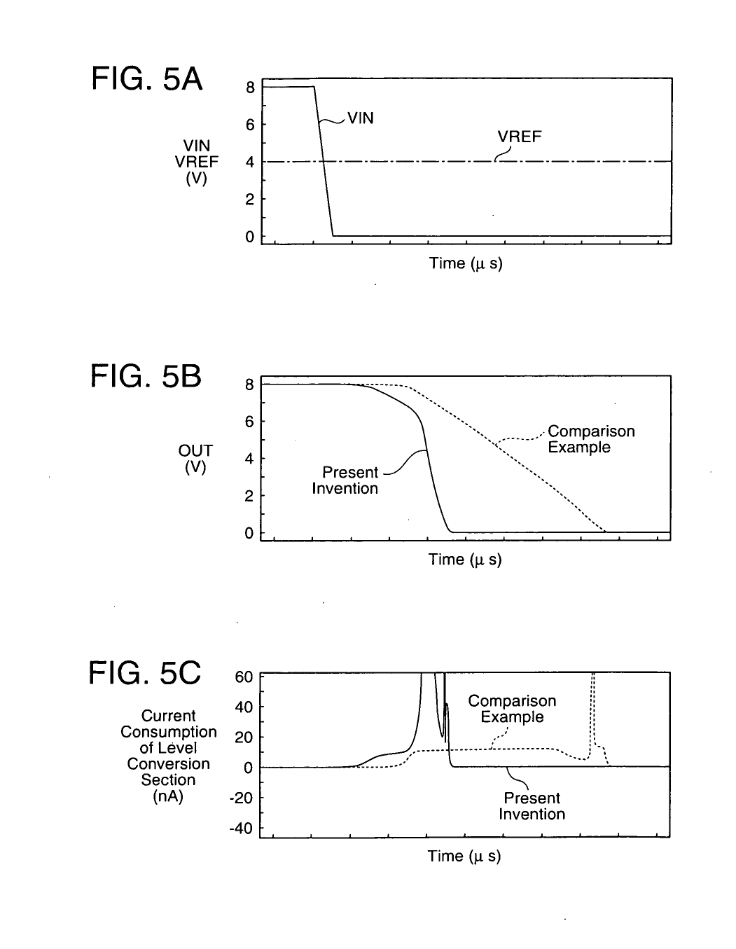

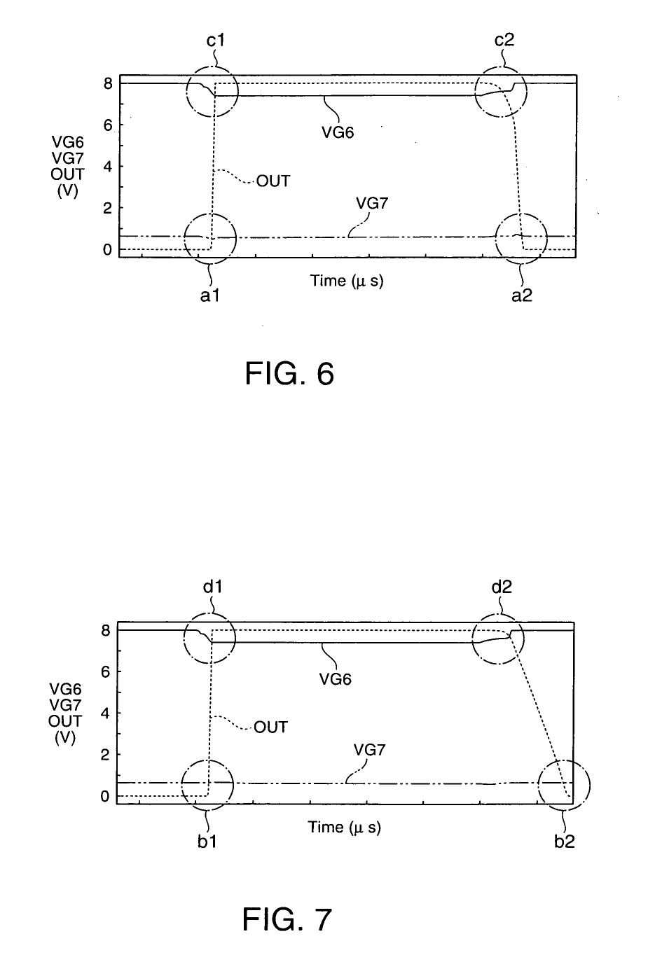

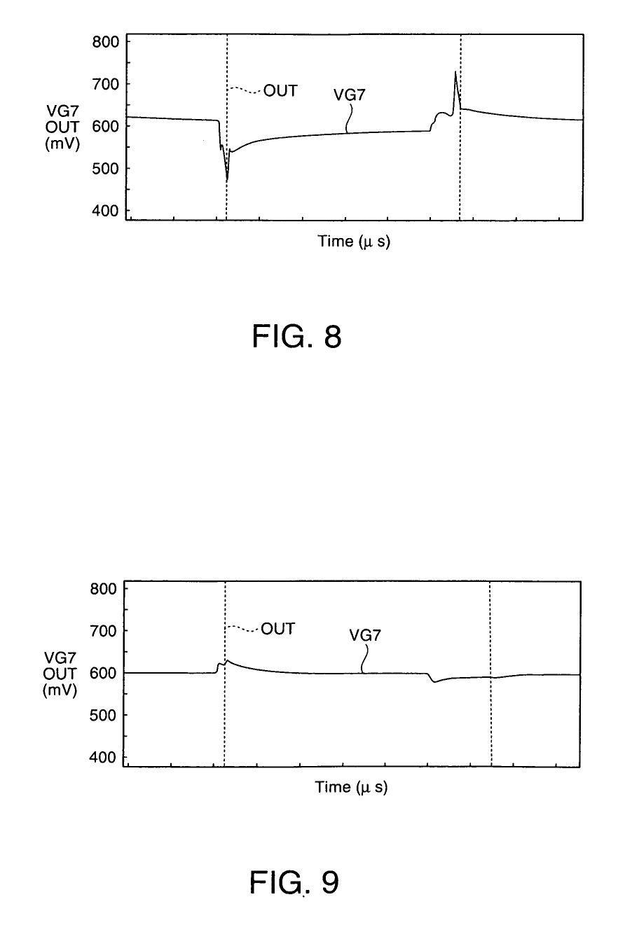

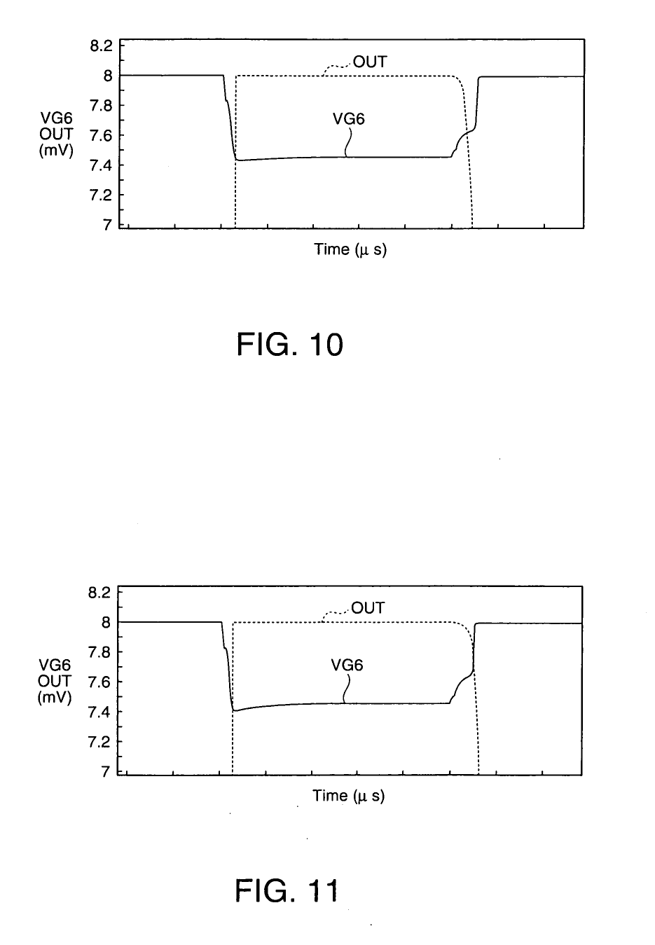

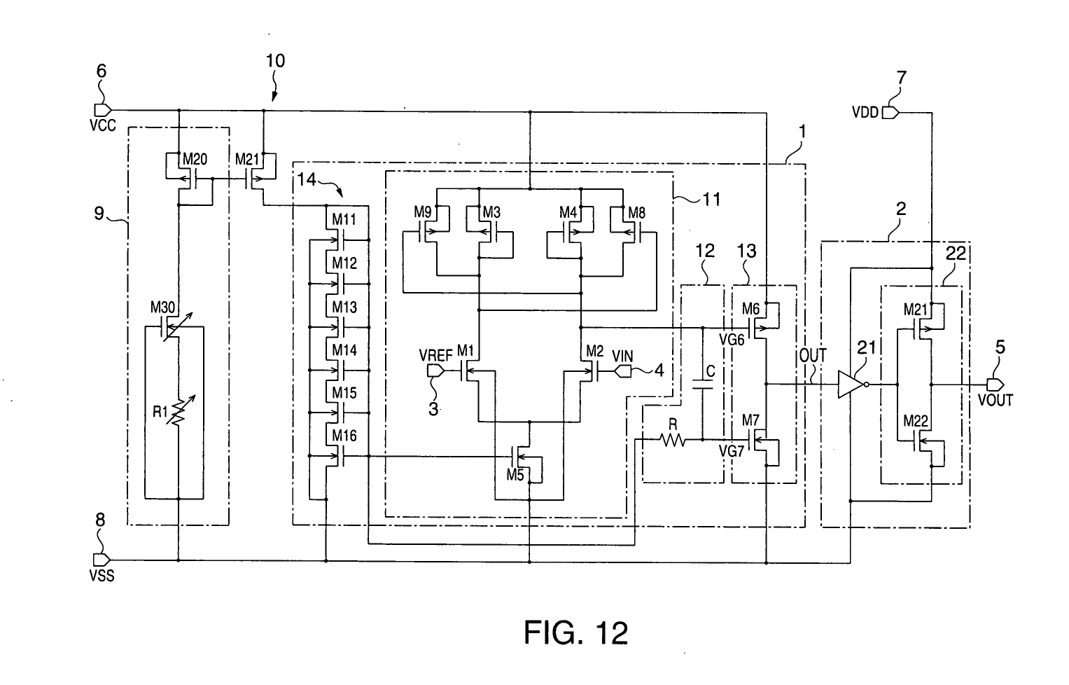

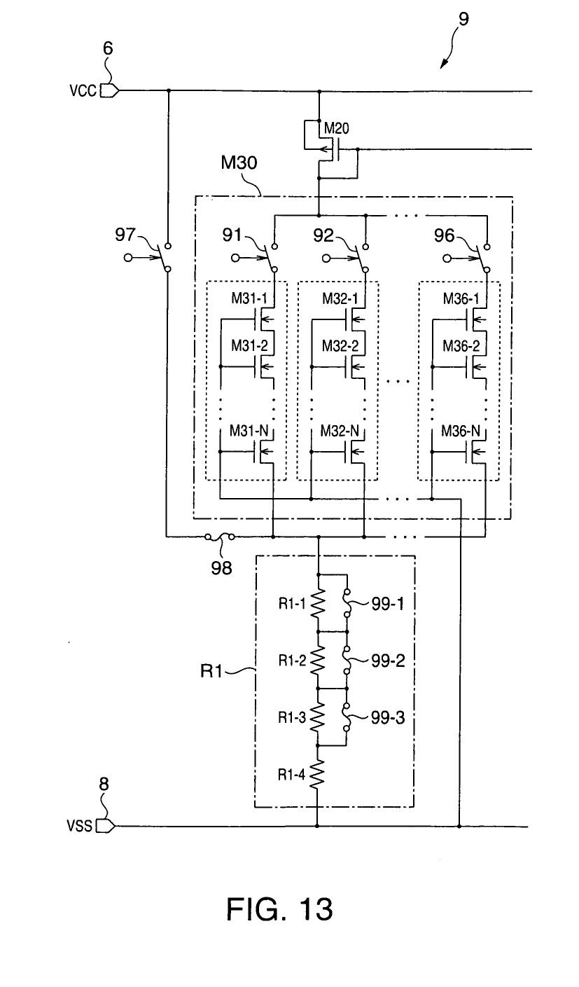

### BRIEF DESCRIPTION OF THE DRAWINGS

[FIG. 1] is a circuit diagram showing a composition example of a first embodiment of the invention.

[FIG. 2] is a schematic diagram showing a composition example of resistances of a differentiation circuit.

[FIG. 3] is a diagram showing an arrangement example of the first embodiment on a semiconductor substrate.

[FIG. 4] shows an input and an output and a simulated waveform of consumed current of a voltage comparing section of the first embodiment.

[FIG. 5] shows an input and an output and a simulated waveform of consumed current of a level converter section of the first embodiment.

[FIG. 6] shows simulated waveforms at primary nodes within the first embodiment.

[FIG. 7] shows simulated waveforms at primary nodes within a voltage comparator without a differentiation circuit, which correspond to the respective nodes of the first embodiment.

[FIG. 8] is an enlarged view of portions encircled by dot-and-dash lines a1 and a2 of FIG. 6.

[FIG. 9] is an enlarged view of portions encircled by dot-and-dash lines b1 and 2 of FIG. 7.

[FIG. 10] is an enlarged view of portions encircled by dot-and-dash lines c1 and c2 of FIG. 6.

[FIG. 11] is an enlarged view of portions encircled by dot-and-dash lines d1 and d2 of FIG. 7.

[FIG. 12] is a circuit diagram showing a composition example of a second embodiment of the present invention.

[FIG. 13] is a circuit diagram showing a composition example of a constant current circuit.

[FIG. 14] is a circuit diagram showing a composition of a conventional voltage comparator.

[FIG. 15] shows waveform examples of respective sections of a conventional voltage comparator.

### DETAILED DESCRIPTION OF PREFERRED EMBODIMENTS

Hereinbelow, embodiments of the present invention will be described with reference to the drawings.

### First Embodiment

A first embodiment of a voltage comparator in accordance with the present invention is equipped with, as shown in FIG. 1, a voltage comparing section (a comparing section) 1 that compares an input voltage VIN with a reference voltage VREF and outputs an output OUT according to the comparison result, and a level convertor section (a level shifter section) 2 that level-converts the output OUT of the voltage comparing section 1 and outputs an output voltage VOUT.

Also, the first embodiment is equipped with an input terminal 3 for inputting a reference voltage VREF, an input terminal 4 for inputting an input voltage VIN, an output terminal 5 for outputting an output voltage VOUT, a power supply terminal 6 for supplying a power supply voltage VCC, a power supply terminal 7 for supplying a power supply voltage VDD that is relatively lower than the power supply voltage VCC, and a ground terminal 8 for supplying a power supply voltage VSS.

Furthermore, the first embodiment is integrated into a circuit on a semiconductor substrate. A composition example thereof will be described later. It is noted that the present invention is also applicable to a case where a voltage other than the reference voltage is inputted to the input terminal 3. For example, the input voltage VIN may be inputted in the input terminal 3, and the reference voltage VREF may be inputted in the input terminal 4. Also, it is possible to input a variable signal in the input terminal 3, such as, an inversion signal of the input voltage VIN or the like.

Here, as the power supply voltage VCC, 0.9˜8.0 [V] is applied to the voltage comparing section 1, which can be operated with the power supply voltage within this range. Also, the power supply voltage VDD of 0.9˜1.2 [V] is applied to the level conversion section 2, which can be operated with the power supply voltage within this range. It is noted that, here, a relation of VCC≧VDD is always maintained.

The voltage comparing section 1 is equipped with, as shown in FIG. 1, a differential amplifier circuit 11, a differentiation circuit 12, an output amplifier circuit 13 and a current mirror circuit 14.

The input voltage VIN and the reference voltage VREF are inputted in the differential amplifier circuit 11, which then differentially amplifies the inputted voltages (signals) and provides an output. For this reason, the differential amplifier circuit 11 is equipped with N type MOS transistors M1 and M2 that compose a differential pair, P type MOS transistors M3 and M4 that compose a load, an N type MOS transistor M5 for electrical current source, and P type MOS transistors M8 and M9 for voltage positive feedback.

Described more concretely, the MOS transistor M1 has a gate connected to the input terminal 3, and the reference voltage VREF is applied to the gate. The MOS transistor M2 has a gate connected to the input terminal 4, and the input voltage VIN is applied to the gate. The MOS transistors M1 and M2 have commonly connected sources, and the commonly connected portion is connected to a drain of the MOS transistor M5. The MOS transistor M1 has a drain connected to a drain of the MOS transistor M3. The MOS transistor M2 has a drain that is connected to a drain of the MOS transistor M4.

The MOS transistor M3 has a gate that is connected to its own drain. The MOS transistor M3 has a source to which the power supply voltage VCC is applied. The MOS transistor M4 has a gate that is connected to its own drain. The MOS transistor M4 has a source to which the power supply voltage VCC is applied.

The MOS transistor M5 has a gate that is connected to gates of MOS transistors M11˜M16 to be described below, and connected to one end side of a resistor R1 of the differentiation circuit 12. The MOS transistor M5 has a source to which the power supply voltage VSS is applied.

The MOS transistor M8 has a drain that is connected to the drain of the MOS transistor M2. The MOS transistor M8 has a source to which the power supply voltage VCC is applied. The gate of the MOS transistor M8 is connected to the drain of the MOS transistor M1. The MOS transistor M9 has a drain that is connected to the drain of the MOS transistor M1. The MOS transistor M9 has a source to which the power supply voltage VCC is applied. The gate of the MOS transistor M9 is connected to the drain of the MOS transistor M2.

It is noted that the power supply voltage VSS is applied to substrate terminals of the MOS transistors M1, M2 and M5, and the power supply voltage VCC is applied to substrate terminals of the MOS transistors M3, M4, M8 and M9.

The differentiation circuit 21 differentiates (time-wise differentiates) an output voltage of the differential amplifier circuit 11, and adds (supplies) the differentiated voltage as a bias voltage to the gate of the MOS transistor M7 for constant current of the output amplifier circuit 13.

For this reason, the differentiation circuit 12 is comprised of a capacitor C and a resistance R, as shown in FIG. 1. One end side terminal of the capacitor C is connected to the drains of the MOS transistors M2 and M4 that define an output terminal of the differential amplifier circuit 11. The other end side terminal of the capacitor C is connected to one end side terminal of the resistance R and the gate of the MOS transistor M7. The other end side terminal of the resistance R is connected to the gate of the MOS transistor M5.

The output amplifier circuit 13 receives an output of the differential amplifier circuit 11, and amplifies the input and outputs the same.

Therefore, the output amplifier circuit 13 is a source grounded amplifier circuit that is comprised of a P type MOS transistor M6 that receives an output of the differential amplifier circuit 11 and an N type MOS transistor M7 for constant current which functions as a load of the MOS transistor M6.

The MOS transistor M6 has a gate to which an output of the differential amplifier circuit 11 is inputted. The MOS transistor M6 has a source to which the power supply voltage VCC is applied. The MOS transistor 6 has a drain that is connected to a drain of the MOS transistor M7 and an input terminal of an inverter 21 of the level converter section 2 to be described below. The power supply voltage VCC is applied to a substrate terminal of the MOS transistor M6.

The MOS transistor M7 has a gate to which a voltage (a DC bias voltage that is generated through conversion of a bias current VI to a voltage by the transistors M11˜M16) equivalent to the voltage applied to the gate of the MOS transistor M5, and the differentiated voltage of the differentiation circuit 12 are added. The power supply voltage VSS is applied to the source and a substrate terminal of the MOS transistor M7.

The current mirror circuit 14 is comprised of, as shown in FIG. 1, serially connected N type MOS transistors M11˜M16 and MOS transistors M5 and M7, and flows a predetermined electric current in proportion to the current flowing through the MOS transistors M11˜M16 to the MOS transistor M5 and the MOS transistor M7, respectively.

Furthermore, the constant current VI is supplied to a drain of the MOS transistor M11, and a source of the MOS transistor M16 is connected to the ground terminal 8. Also, gates of the MOS transistors M11˜M16 are commonly connected, and the commonly connected portion is connected to the drain of the MOS transistor M11 and the gate of the MOS transistor M5, and also connected to the gate of the MOS transistor M7 through the resistance R. The power supply voltage VSS is applied to substrate terminals of the MOS transistors M11˜M16.

It is noted that, here, an example in which a plurality of N type MOS transistors are connected in series is exemplified, but the MOS transistors M11˜M16 may be formed with one N type MOS transistor.

The level converter section 2 is equipped with, as shown in FIG. 1, an inverter 21 and a CMOS inverter 22, receives an output OUT of the voltage comparing section 1, and level-converts the input and outputs an output voltage VOUT.

The inverter 21 receives an output OUT of the voltage comparing section 1, and inverts the logic level of the input and outputs the same. The CMOS inverter 22 receives the inversion output of the inverter 21, and inverts the logic level of the input and outputs the same.

The CMOS inverter 22 is comprised of a P type MOS transistor M21 and an N type MOS transistor M22. The MOS transistors M21 and M22 have gates commonly connected, and the output of the inverter 21 is inputted to the commonly connected section thereof. The power supply voltage VDD is applied to a source and a substrate terminal of the MOS transistor M21. The power supply voltage VSS is applied to a source and a substrate terminal of the MOS transistor M22. Drains of the MOS transistors M21 and M22 are commonly connected, and the commonly connected section is connected to the output terminal 5.

Next, a concrete composition example of the resistance R of the differentiation circuit 12 of FIG. 1 will be described with reference to FIG. 2.

The resistance R of the differentiation circuit 12 is disposed on a semiconductor substrate. In other words, the resistance R may be composed of, for example, polysilicon resistance (hereafter referred to as resistance), wherein the resistance has predetermined width and length as a whole according to the resistance value necessary for composing the differentiation circuit 12.

The resistance is divided and arranged in a manner that, when disposed on the semiconductor substrate, parasitic capacitances formed would not harm the operation of the differentiation circuit 12. In other words, the resistance is divided and arranged in such a manner that, as the resistance is arranged on the semiconductor substrate, the parasitic capacitance between one end and the other end of the resistor R formed is minimized.

In order to secure the desired differentiation characteristic in the differentiation circuit 12, the parasitic capacitance connected in parallel with the resistance needs to be suppressed to a minimum. In particular, the greater the resistance value of the resistance R of the differentiation circuit 12, the stronger the reduction of the parasitic capacitance is desired. If the required resistance value of the resistance R can be realized by a single resistance, no substantial problem arises. However, when it is formed from a plurality of divided resistances, the parasitic capacitance among the resistances contributes to the capacitance component between one end and the other end of the resistance R. The longer the opposing distance between parallel divided resistances, the greater the parasitic capacitance between the resistances, and the entire parasitic capacitance of the resistances amounts to a serially added value of the respective parasitic capacitances. Therefore, in order to reduce the parasitic capacitance value between one end and the other end of the resistance R, it is preferred to use resistances that are divided as many as possible within an allowable area. This is particularly effective in reducing the parasitic capacitance between one end and the other end of the resistance R, because this makes it possible to concurrently obtain effects of minimizing the parasitic capacitance between resistances and increasing the number of serially connected parasitic capacitances.

As shown in FIG. 2, the resistance is divided into N pieces of resistances R-1˜R-N, and each of the divided resistances R-1˜R-N is arranged according to a predetermined rule on the semiconductor substrate (not shown).

In the example of FIG. 2, the resistances R-1˜R-N have a predetermined length, and are regularly arranged in the up and down direction on the semiconductor substrate at predetermined intervals thereby forming one column, whereby three columns are formed as a whole. Also, the resistances R-1˜R-N are connected in series. In other words, the resistances R-1˜R-N are mutually connected through metals 121, and electrically connected in series as a whole.

The resistances R-1˜R-N may preferably be divided in resistances having the same resistance value. In other words, when they are arranged in three columns as shown in FIG. 2, a section 121-1 connecting the first column and the second column and a section 121-2 connecting the second column and the third column shall not to be formed from polysilicon resistance, but may preferably be connected by metal. This makes it easier to change the resistance value.

It is noted that it is not necessary to arrange the resistances R-1˜R-N in three columns (plural columns) as shown in FIG. 2. In other words, each of the resistances R-1˜R-N is subject to restrictions such as their arrangement location and arrangeable range (area), and therefore it is sufficient as long as they are arranged on the semiconductor substrate in a manner that the overall parasitic capacitance can be minimized within such a range of restrictions.

Next, the voltage comparator in accordance with the first embodiment shown in FIG. 1 may be used as a part of components of a variety of electronic devices (such as a contactless IC card), and integrated into a circuit on a semiconductor substrate. Accordingly, a composition example thereof on a semiconductor substrate will be described with reference to FIG. 3.

When the voltage comparator of FIG. 1 is used as a part of components of an electronic device, the electronic device is integrated into a circuit on a semiconductor substrate 30, as shown in FIG. 3, and the voltage comparator 31 of FIG. 1 is disposed in a portion on the semiconductor substrate 30.

Along the outer peripheral section of the voltage comparator 31 is arranged the resistances R-1˜RN of the differentiation circuit 12 shown in FIG. 2. More specifically, the voltage comparator 31 is surrounded along its circumference by the resistances R-1˜RN, such that the voltage comparator 31 can prevent influence of noise (external noise) generated by other components. In other words, the resistances R-1˜RN are arranged to have a shield effect that shields external noise other than internal noise generated by the voltage comparator 31. This positively utilizes the high-frequency noise reducing effect provided by a low pass filter that is formed by each of the resistances and a parasitic capacitance of its opposing substrate.

In accordance with such an arrangement composition, even if circuits that generate or would likely generate noise (noise generating sources), such as, for example, high-speed switching circuits 32 and 33 that perform switching operations at higher speed than the voltage comparator are disposed adjacent to the voltage comparator 31, as shown in FIG. 3, the voltage comparator 31 can exclude influence of noise that accompanies the switching operation of the high-speed switching circuits 32 and 33.

Next, an example of operations of the first embodiment will be described with reference to FIG. 4.

It is assumed that an input voltage VIN and a reference voltage VREF shown in FIG. 4(A) are inputted to the voltage comparator of FIG. 1. In this case, when the input voltage VIN rises, an output OUT of the voltage comparing section 1 rises after a predetermined time from the rising (see a solid line in FIG. 4(B)). Also, accompanying this, an output voltage VOUT of the output terminal 5 that is an output of the level converter section 2 rises (see a solid line in FIG. 4(C)).

Thereafter, as the input voltage VIN falls, the output OUT of the voltage comparing section 1 falls after a predetermined time from the falling (see the solid line in FIG. 4(B)). Also, accompanying this, the output voltage VOUT of the output terminal 5 falls (see the solid line of FIG. 4(C)).

Here, for comparison of the effects provided by the differentiation circuit 12 of the first embodiment, description will be made as to waveforms at relevant sections of a circuit in which the differentiation circuit 12 is omitted from the voltage comparator shown in FIG. 1 (corresponding to the conventional circuit shown in FIG. 4), in other words, a voltage comparator in which the capacitor C and the resistance R in the differentiation circuit 12 are omitted, and the gate of the MOS transistor M5 is connected to the gate of the MOS transistor M7 (hereafter referred to as the voltage comparator for comparison).

With the voltage comparator for comparison that omits the differentiation circuit 12 (see FIG. 1), the voltage comparing section 1 provides an output OUT as indicated by a broken line in FIG. 4(B), and the output terminal 5 provides an output voltage VOUT as indicated by a broken line in FIG. 4(C).

According to FIGS. 4(B) and (C), the first embodiment can substantially shorten the falling time of the output OUT of the voltage comparing section 1, compared to the voltage comparator for comparison (see FIG. 4(B)) and, as a result, the falling time of the output voltage VOUT of the output terminal 5 can be substantially shortened, compared to the voltage comparator for comparison (see FIG. 4(C)), such that operation at higher speed can be achieved.

Next, with the operation of the first embodiment described above, the current (consumed current) flows through the voltage comparing section 1 as indicated by a solid line in FIG. 4(D). Also, when the input voltage VIN falls (see a solid line in FIG. 5(A)) and, accompanying this, the output OUT of the voltage comparing section 1 falls (see a solid line in FIG. 5(B)), a current (consumed current) flows through the level converter section 2 as indicated by a solid line in FIG. 5(C).

On the other hand, in the voltage comparator for comparison, the voltage comparing section 1 has a consumed current as indicated by a broken line in FIG. 4(D), and the level conversion section 2, when the output OUT of the voltage comparing section 1 falls, has a current consumption as indicated by a broken line in FIG. 5(C).

According to FIG. 4(D), the average value of consumed current at the voltage comparing section 1 of the first embodiment can be made smaller than the average value of consumed current of the voltage comparator for comparison. Also, according to FIG. 5(C), the consumed current in the level conversion section 2 of the voltage comparator for comparison has a smaller peak value, but the fall time of the output of the voltage comparing section 1 becomes longer than the first embodiment (see a broken line in FIG. 5(B)). For this reason, the current consumption by the level conversion section 2 of the first embodiment is lower than the current consumption by the voltage comparator for comparison.

Therefore, in accordance with the first embodiment, the current consumption can be reduced, compared to the voltage comparator for comparison.

Next, examples of waveforms at primary nodes within the first embodiment will be described with reference to FIG. 6˜FIG. 11.

These waveform examples are obtained when waveforms indicated in FIG. 4(A) are inputted as an input voltage VIN and a reference voltage VREF. FIG. 6 shows gate voltages VG6 and VG7 of the MOS transistors M6 and M7 and an output OUT of the voltage comparing section 1 in accordance with the first embodiment at that moment. FIG. 7 shows gate voltages VG6 and VG7 of the MOS transistors M6 and M7 and an output OUT of the voltage comparing section 1 in the voltage comparator for comparison at that moment.

FIG. 8 is an enlarged view of portions encircled by dot-and-dash lines a1 and a2 in FIG. 6. FIG. 9 is an enlarged view of portions encircled by dot-and-dash lines b1 and b2 in FIG. 7. FIG. 10 is an enlarged view of portions encircled by dot-and-dash lines c1 and c2 in FIG. 6. FIG. 11 is an enlarged view of portions encircled by dot-and-dash lines d1 and d2 in FIG. 7.

According to FIG. 8 and FIG. 9, the gate voltage VG7 of the MOS transistor M7 in accordance with the first embodiment is placed in a state in which a differentiated voltage of the differentiation circuit 12 is added (see FIG. 1). At this time, by appropriately selecting values of C and R, the gate voltage VG7 of the MOS transistor M7 can be made to reduce at the time of rising of the output OUT of the output amplifier circuit 13 such that the bias current flowing to the MOS transistor 6 reduces, and to increase at the time of falling thereof such that the bias current increases.

Therefore, in accordance with the first embodiment, higher response speed can be achieved, compared to that of the voltage comparator in accordance with the comparison example.

Further, although not illustrated in the first embodiment, a voltage limiter circuit using a diode or a diode-connected MOS transistor can be inserted between the drain of the MOS transistors M6 and M7, in other words, the output OUT terminal of the voltage comparing section 1, and the VSS power supply terminal 8. In this case, it is possible to further shorten the fall time, whereby higher speed than that of the circuit shown in FIG. 1 can be achieved.

The feature of inserting a voltage limiter in this manner is also applicable to a second embodiment to be described below.

### Second Embodiment

A second embodiment of a voltage comparator in accordance with the present invention will be described with reference to FIG. 12.

The second embodiment is based on the composition of the first embodiment shown in FIG. 1, and includes a constant current circuit 9 and a current mirror circuit 10 shown in FIG. 12 added thereto.

With the composition of the first embodiment, when the current value inputted in the current mirror circuit 14 varies, the current value flowing in the constant current transistors M5 and M7 also varies in proportion thereto. As a result, the overall operation speed (the response delay time) of the voltage comparator also varies.

Therefore, in accordance with the second embodiment, a highly accurate constant current biasing device is added to the first embodiment, whereby a voltage comparator with small variations in its operation speed can be realized.

It is noted that the second embodiment is based on the composition of the first embodiment shown in FIG. 1, and therefore the same constituent elements are appended with the same reference numbers and their description will be omitted as much as possible.

The constant current circuit 9 is equipped with, as shown in FIG. 12, a P type MOS transistor M20, a depletion N type MOS transistor 30 whose transistor size is freely adjustable, and a resistance R1 whose resistance value is freely adjustable, which are connected in series between a power supply terminal 6 and a ground terminal 8. Thus, the constant current circuit 9 is capable of generating a desired constant current by adjusting the transistor size of the MOS transistor M30 and the resistance value of the resistance R1.

Here, the transistor size adjustment is done for the purpose of adjusting the constant current initial value, and the resistance value adjustment is done for the purpose of adjusting the temperature coefficient of the current value. The constant current initial value is a value given when a predetermined voltage with a predetermined current is applied at a predetermined temperature (for example, 25° C.) in a state prior to making the transistor size adjustment.

The MOS transistor M30 is formed from N pieces of MOS transistors having different transistor sizes so as to be able to set a desired transistor size, and at least one among the N pieces can be selected and used.

The resistance R1 is formed from M pieces of resistances having different resistance values so as to be able to set a desired resistance value, and at least one among the M pieces can be selected and used.

The current mirror circuit 10 is comprised of a P type MOS transistor M20 and a P type MOS transistor M21, such that a current in proportion to the current flowing through the constant current circuit 9 flows in the MOS transistor M21.

Next, a concrete composition example of the constant current circuit 9 shown in FIG. 12 will be described with reference to FIG. 13.

The constant current circuit 9 is equipped with, as shown in FIG. 13, a P type MOS transistor M20, N type MOS transistors M31-1˜M31-N, M32-1˜M32-N, . . . M36-1˜M36-N, resistances R1-1˜R1-4, transistor selection switches 91˜96, a switch 97, a fuse 98, and resistance selection fuses 99-1˜99-3.

The MOS transistor M20 is diode-connected. In other words, the gate of the MOS transistor M20 is connected to its own drain. Also, the power supply voltage VCC is applied to a source of the MOS transistor M20.

The MOS transistors M31-1˜M31-N, M32-1˜M32-N, . . . M36-1˜M36-N are selected by the transistor selection switches 91˜96, as described below, and those selected among the MOS transistors M31-1˜M31-N, M32-1˜M32-N, . . . M36-1˜M36-N can be used while being connected in parallel.

For this reason, the MOS transistors, M31-1˜M31-N are connected in series as shown in FIG. 13, and the drain of the MOS transistor M31-1 is connected to the drain of the MOS transistor M20 through the switch 91. Similarly, the MOS transistors M32-1˜M32-N, . . . M36-1˜M36-N are connected in series, respectively, as shown in FIG. 13, and the drains of the MOS transistors M32-1˜M32-N, . . . M36-1˜M36-N are connected to the drain of the MOS transistor M20 through the switches 92˜96, respectively.

Gates of the MOS transistors M31-1˜M31-N, M32-1˜M32-N, . . . M36-1˜M36-N are connected to the ground terminal 8, respectively. Also, although omitted in FIG. 13, substrate terminals of the MOS transistors M31-1˜M31-N, M32-1˜M32-N, . . . M36-1˜M36-N are connected to the ground terminal 8, respectively.

Here, in the MOS transistors M31-1˜M31-N, M32-1˜M32-N, . . . M36-1˜M36-N, the MOS transistors that are connected in series are in the same size (transistors with the same gate length and gate width), respectively. On the other hand, among units of the serially connected MOS transistors, the MOS transistors in each unit are different in size from one unit to another. Accordingly, the MOS transistors M31-1˜M31-N are in the same size, but the MOS transistors M31-1, M32-1 . . . M36-1 are different in size, respectively.

The resistances R1-1˜R1-3 can be selected by the resistance selection fuses 99-1˜99-3 as described below, such that the selected ones of the resistances R1-1˜R1-3 and the resistance R1-4 can be connected in series and used.

For this reason, the resistances R1-1˜R1-4 have mutually different resistance values, and are connected in series in a manner shown in FIG. 13. For example, the resistances R1-1˜R1-4 have relatively large differences, and when a resistance value of 10 [MΩ] is required, the resistance R1-1 is 1 [MΩ], the resistance R1-2 is 2.5 [MΩ], the resistance R1-3 is 5 [MΩ], and the resistance R1-4 is 5 [MΩ].

One end side of the resistance R1-1 is connected to sources of the MOS transistors M31-N˜M36-N, respectively, and connected to the power supply terminal 6 through the fuse 98 and the switch 97. Also, one end side of the resistance R1-4 is connected to the ground terminal 8. Furthermore, each of the fuses 99-1˜99-3 is connected to both ends of each of the resistances R1-1˜R1-3, respectively.

Next, a method of selecting and setting the MOS transistors and the resistances of the constant current circuit 9 having such a composition will be described with reference to FIG. 13.

First, a procedure of selecting and setting at least one of the resistances R1-1˜R1-4 will be described.

In this case, the switch 97 is turned on based on a signal from an unshown selection circuit (a test circuit), thereby applying the power supply voltage VCC to one end of the resister R1-4 and the power supply voltage VSS to the other end thereof. In this instance, by measuring a current I flowing from the power supply terminal 6 to the ground terminal 8, the resistance value of the resistance R1-4 is obtained based on the power supply voltage VCC and the measured current I. When the obtained resistance value is within an allowable range of a necessary resistance value, the resistance R1-4 is selected. In this case, the fuses 99-1˜99-3 are left without being cut, and the fuse 98 is cut.

On the other hand, when the obtained resistance value of the resistance R1-4 is not within the allowable range of the necessary resistance value, the switch 97 is turned off once, and one of the fuses 99-1˜99-3 is selected and cut according to the obtained resistance value. For example, cutting the fuse 99-1 sets the resistance R1-1 and the resistance R1-4 in a state of being connected in series. The switch 97 is turned on in this state, and the power supply voltage VCC is applied to both ends of the serially connected resistance R1-1 and R1-4.

In this instance, by measuring a current I flowing from the power supply terminal 6 to the ground terminal 8, the resistance value of the serial circuit of the resistance R1-1 and resistance R1-4 is obtained based on the power supply voltage VCC and the measured current I. When the obtained resistance value is within an allowable range of the necessary resistance value, the resistances R1-1 and R1-4 are selected. In this case, the fuses 99-2 and 99-3 are left without being cut, and the fuse 98 is cut.

In this manner, by selecting and setting at least one of the resistances R1-1˜R1-4, the set resistance can be used thereafter.

Next, a procedure of selecting the MOS transistors M31-1˜M31-N, M32-1˜M32-N, . . . M36-1˜M36-N will be described.

In this case, predetermined switches among the switches 91˜96 are turned on based on a signal from an unshown selection circuit (a test circuit). Now, for example, if the switch 91 is turned on, the MOS transistors M31-1˜M31-N are selected, one end of the selected MOS transistors M31-1˜M31-N is connected to the MOS transistor M20, and the other end thereof is connected to selected ones of the resistances R1-1˜R1-4.

By this, the constant current circuit 9 forms a circuit with the selected elements and generates an electric current according to the formed circuit, and therefore the electric current is measured. The measured electric current is within an allowable range of a necessary constant current, the MOS transistors M31-1˜M31-N are to be selected. In this case, when the constant current circuit 9 is in use, the switch 91 alone is turned on, and the switches 92˜96 are turned off.

On the other hand, if the selected MOS transistors M31-1˜M31-N do not fall within the allowable range of the necessary constant current, for example, one of the switches 92˜96 may be further selected and turned on according to the measured current value. For example, when the switch 96 is turned on, the MOS transistors M36-1˜M36-N are selected, which are connected in parallel with the aforementioned MOS transistors M31-1˜M31-N that have already been selected (see FIG. 13).

In this state, a current flowing through the constant current circuit 9 is measured. If the measured current is within the allowable range of the necessary constant current, the MOS transistors M31-1˜M31-N and the MOS transistors M36-1˜M36-N are selected. In this case, when the constant current circuit 9 is in use, the switches 91 and 96 are turned on, and the switches 92˜95 are turned off.

It is noted that, in accordance with another embodiment, the switch 91 that has been turned on in the first adjustment may be turned off, and at least one of the switches 92˜95 may be turned on.

In a manner described above, the second embodiment is based on the composition of the first embodiment, and thus can realize actions and effects similar to those of the first embodiment.

Also, the second embodiment is equipped with the constant current circuit 9, and the constant current circuit 9 is equipped with the selectable MOS transistors M31-1˜M31-N, M32-1˜M32-N, . . . M36-1˜M36-N, and the selectable resistances R1-1˜R1-4. Therefore, even if size errors of the MOS transistors composing the constant current circuit 9 and resistance errors are relatively large, a required constant current can be generated with high accuracy, such that the actions and effects of the first embodiment can be realized with high stability, while making them harder to be affected by manufacturing variations and temperature changes.

It is noted that, in accordance with the present embodiment, the initial current value is adjusted by changing the number of groups of serially connected transistors to be connected in parallel by the switches. However, a group of serially connected transistors may be provided without using parallel connection, and switches provided between sources and drains of the respective transistors may be used to change the number of the serially connected transistors thereby changing the initial current value.

### Embodiment of Electronic Device

Next, embodiments of electronic devices in accordance with the present invention will be described.

In the embodiments of electronic devices, the voltage comparator described above is applied to a variety of electronic devices. In other words, in the embodiments of electronic devices, the voltage comparator described above is applied to, for example, contactless IC cards, mobile phones, car navigation systems, video cameras, electronic still cameras and the like.

According to the embodiments of electronic devices with such a composition, the use of the voltage comparator described above makes it possible to realize a voltage comparator that operates at high speed without increasing its current consumption. Also, as shown in FIG. 3, when the voltage comparator is arranged and disposed on a semiconductor substrate, the voltage comparator 31 can be protected from external noise by the resistances R-1˜R-N.

1. A voltage comparator comprising:
a differential amplifier circuit that is configured to differentially amplify differentially inputted signals and provides an output;
an output amplifier circuit that is configured to amplify the output of the differential amplifier circuit and provides an output; and
a differentiation circuit that is configured to differentiate the output of the differential amplifier circuit,
a differentiated output of the differentiation circuit being added to a bias voltage of a constant current transistor of the output amplifier circuit.

2. A voltage comparator recited in claim 1,
the output amplifier circuit having an input transistor in which an output of the differential amplifier circuit is inputted,
the constant current transistor supplying a constant current to the input transistor, and
the constant current transistor being controlled by the output of the differentiation circuit.

3. A voltage comparator recited in claim 1,
the differentiation circuit being formed from a capacitor and a resistance,
one end of the capacitor is connected to an output of the differential amplifier circuit,
one end of the resistance is connected to a bias current, and
other end of the capacitor and other end of the resistance are connected to a gate electrode of the constant current transistor.

4. A voltage comparator recited in claim 3,
the resistance being disposed above a semiconductor substrate and has a predetermined resistance value, and
the resistance being divided into a plurality of divided resistances, and first˜Nth divided resistances (N is an integer greater than 1) among the plurality of divided resistances being sequentially disposed at a predetermined interval on the semiconductor substrate and connected in series,
wherein each of the first˜Nth divided resistances has
a first side and a second side that extend in a first direction,
a third side and a fourth side shorter than the first side and extending in a second direction perpendicular to the first direction,
a first contact section provided adjacent to the third side, and
a second contact section provided adjacent to the fourth side, and wherein the first˜Nth divided resistances are such that
the first contact section of a (2n−1)th divided resistance and the first contact section of a (2n)th divided resistance are electrically connected by a first conductive layer provided in an upper layer with respect to the plurality of resistances,
the second contact section of the (2n)th divided resistance and the second contact section of a (2n+1)th divided resistance are electrically connected by a second conductive layer provided in an upper layer with respect to the plurality of resistances, and
the first˜Nth divided resistances are electrically connected in series.

5. A voltage comparator recited in claim 3, the resistance being disposed around the differential amplifier circuit.

6. A voltage comparator recited in claim 1, further comprising a level converter circuit that converts the level of an output of the output amplifier circuit, and
wherein the level converter circuit operates with a power supply voltage lower than a power supply voltage for the differential amplifier circuit and the output amplifier circuit.

7. A voltage comparator recited in claim 1, further comprising a constant current circuit that generates a predetermined electric current, and a current mirror circuit that circulates a constant electric current to the constant current transistor based on the electric current generated by the constant current circuit.

8. A voltage comparator recited in claim 7, wherein the constant current circuit is equipped with a diode-connected first transistor, n pieces of freely selectable second transistors having gates to which a predetermined potential is applied and having different transistor sizes, and m pieces of freely selectable resistances having different resistance values.

9. A voltage comparator recited in claim 8,
the n pieces of second transistors being connected in parallel and
the m pieces of resistances being connected in series, and
further comprising
a first selection device that selects at least one of the n pieces of transistors connected in parallel; and
a second selection device that selects at least one of the m pieces of resistances connected in series.

10. A voltage comparator recited in claim 9,
each of the n pieces of transistors being comprised of p pieces of transistors having the same size,
wherein the p pieces of transistors are connected in series and have gates commonly connected, and a predetermined potential is applied to the connected section thereof, and
each of the n pieces of transistors has a switch for selecting the p pieces of transistors connected in series.

11. A voltage comparator comprising:
a differential amplifier circuit that differentially amplifies differentially inputted signals and provides an output;
a bias circuit that generates a bias voltage from a constant electric current;
a differentiation circuit to which the output of the differential amplifier circuit and the bias voltage are applied; and
an output amplifier circuit to which the output of the differential amplifier circuit and an output of the differentiation circuit are applied.

12. An electronic device including the voltage comparator recited in claim 1.

13. A voltage comparator comprising:
a differential amplifier circuit that differentially amplifies a first input signal and a second input signal and provides an output;
a voltage change detection circuit that detects a change amount in the output of the differential amplifier circuit; and
an output amplifier circuit that amplifies the output of the differential amplifier circuit and outputs an amplified signal, wherein
the voltage change detection circuit is configured to add a voltage based on the charge amount to a voltage of the amplified signal when the output of the differential amplifier circuit increases, and
the voltage change detection circuit is configure to subtract a voltage based on the charge amount from a voltage of the amplified signal when the output of the differential amplifier circuit decreases.
